(19) United States
(12) Patent Application Publication
(10) Pub. No.: US 2009/0212979 A1
(43) Pub. Date: Aug. 27, 2009

(54) GLOVE-BASED INPUT DEVICE

(75) Inventors: David Catchings, Fuquay-Varina, NC (US); Ameir Al-Zoubi, Raleigh, NC (US); Matthew Crenshaw, Raleigh, NC (US); John Lewis, Cary, NC (US)

Correspondence Address: CONLEY ROSE, P.C., 5601 GRANITE PARKWAY, SUITE 750, PLANO, TX, 75024, US

(73) Assignee: William Catchings, Raleigh, NC (US)

(21) Appl. No.: 12/390,141

(22) Filed: Feb. 20, 2009

Related U.S. Application Data
(60) Provisional application No. 61/030,824, filed on Feb. 22, 2008.

(51) Int. Cl. H03K 17/94

(52) U.S. Cl. 341/20

(57) ABSTRACT

A glove-based input device is provided. The glove-based input device comprises at least one selector, at least one motion sensor, a processor, a transmitter, and a glove structure adopted for placing over a hand, the glove-structure retaining the selector, the motion sensor, the processor, and the transmitter. The processor receives a selection input from the at least one selector and a motion input from the at least one motion selector. The transmitter is in communication with the processor and is configured to wirelessly transmit the selector input and the motion input to an electronic device.

### CROSS-REFERENCE TO RELATED APPLICATIONS

The present application claims the benefit under 35 U.S.C. §119 of U.S. provisional application Ser. No. 61/030,824 filed Feb. 22, 2008 and entitled “Glove-Based Controller”, hereby incorporated herein by reference for all purposes.

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

Gaming controllers may be used to provide command inputs to control computer-based games. Gaming controllers take a variety of forms. Remote controllers may be used to control presentation audio and video equipment, for example to advance or reverse a displayed chart or slide, to dim or turn up lights, to increase or decrease loudspeaker volume.

### SUMMARY

In an embodiment, a glove-based input device is disclosed. The glove-based input device comprises at least one selector, at least one motion sensor, a processor, a transmitter, and a glove structure adopted for placing over a hand, the glove-structure retaining the selector, the motion sensor, the processor, and the transmitter. The processor receives a selection input from the at least one selector and a motion input from the at least one motion selector. The transmitter is in communication with the processor and is configured to wirelessly transmit the selector input and the motion input to an electronic device.

In another embodiment, a glove-based input device is disclosed. The glove-based input device comprises at least one selector, at least one motion sensor, a processor, and a glove structure adopted for placing over a hand, the glove-structure retaining the selector, the motion sensor, and the processor. The processor receives a selection input from the at least one selector and a motion input from the at least one motion selector and communicates the selection input and the motion input via a wired communication link to an electronic device.

In another embodiment, a glove-based input device is disclosed. The glove-based input device comprises a glove structure adopted for placing over a hand, a plurality of switches retained by finger portions of the glove structure, an at least one motion sensor retained by one of a palm portion of the glove structure and a back-of-hand portion of the glove structure, and a processor. The switches are mechanically biased open and are operable to be closed when pressure is applied between a thumb and the switch. Each switch is operable to provide an indication of an open state and a closed state. The processor is operable to transmit indications of the state of the switches and motion indications to an electronic device to provide inputs to the electronic device.

These and other features will be more clearly understood from the following detailed description taken in conjunction with the accompanying drawings and claims.

### BRIEF DESCRIPTION OF THE DRAWINGS

For a more complete understanding of the present disclosure, reference is now made to the following brief description, taken in connection with the accompanying drawings and detailed description, wherein like reference numerals represent like parts.

FIG. 1 illustrates a glove-based input device according to some embodiments of the disclosure.

FIG. 2 illustrates a glove-based input device providing control inputs to an exemplary electronic device via a wireless communication link according to some embodiments of the disclosure.

FIG. 3 illustrates an exemplary computer system suitable for implementing some aspects of the several embodiments of the disclosure.

### DETAILED DESCRIPTION

It should be understood at the outset that although illustrative implementations of one or more embodiments are illustrated below, the disclosed systems and methods may be implemented using any number of techniques, whether currently known or in existence. The disclosure should in no way be limited to the illustrative implementations, drawings, and techniques illustrated below, but may be modified within the scope of the appended claims along with their full scope of equivalents.

A glove-based input device that is suitable for controlling a variety of electronic devices and/or for providing control inputs to a variety of computer based systems is disclosed. In an embodiment, the glove-based input device promotes conveying motion inputs and selection inputs via a wireless link to a remote electronic device, for example to a computer or to an embedded system. The glove-based input device integrates sensors and/or switches with a fabric structure for wearing on or over the hand. In an embodiment, the glove-based input further may integrate transducer devices, for example vibrators, heaters, one or more light emitting diodes (LEDs), a liquid crystal display (LCD), other viewable displays, speakers, and other feedback components with the fabric structure. The glove-based input device promotes receiving control inputs provided by either one or two hands. In an embodiment, the glove-based input device may promote presenting feedback to a hand of a user, for example vibration feedback, temperature feedback, visual feedback, and/or audio feedback. The glove-based input device may reduce hand fatigue that may sometimes be associated with gripping or holding traditional controllers and/or input devices for extended time durations, for example a game controller and/or a computer mouse. The glove-based input device may promote reliable and substantially continuous correct orientation between a user's fingers and input buttons and/or input selectors, to reduce mistakes of selecting buttons. The glove-based input device may provide an ergonomic replacement for the conventional mouse input device, perhaps providing a needed alternative to handicapped or injured users otherwise unable to use a mouse input device. The glove-based input device may promote more natural and/or intuitive control and/or interaction with electronic systems. The glove-based input device may be preferred as a more aesthetically pleasing input device or as a fashion accessory. While in one embodiment the glove-based input device conveys motion and selection inputs via a wireless link to an electronic device, one skilled in the art will appreciate that some of the advantages of the glove-based input device may be provided when conveying the motion and selection inputs using a wired link to the electronic device.

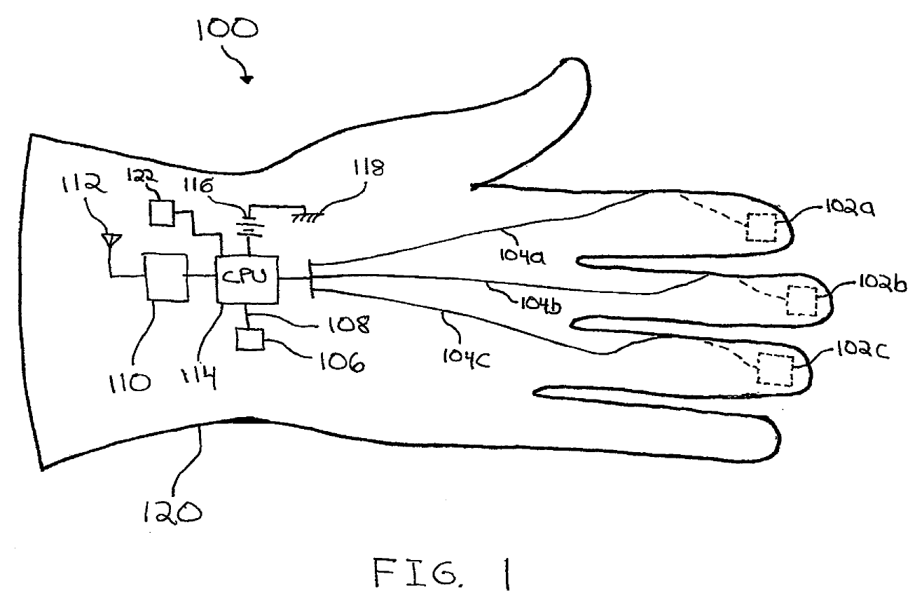

Turning now to FIG. 1, a glove-based input device 100 is described. The glove-based input device 100 comprises a plurality of selectors 102, a plurality of selector couplings 104, a motion sensor 106, a motion coupling 108, a transmitter 110, a wireless emitter 112, a processor 114, a power source 116, an electrical reference 118, and a glove 120. In an embodiment, the glove-based input device 100 may optionally comprise one or more transducers 122. The selectors 102—for example a first selector 102a, a second selector 102b, and a third selector 102c—are actuated by finger manipulation, for example by being compressed between two fingers. The selectors 102 may be switches or other sensors. In an embodiment, the selectors are switches that are mechanically biased open and are operable to close in response to pressure, for example pressure applied to the selector 102 by a thumb press. In an embodiment, the switches may be in one of an open state or a closed state. The selectors 102 are in communication with the processor 114 via the selector couplings 104. For example, the first selector 102a provides selection input to the processor 114 via a first selector coupling 104a, the second selector 102b provides selection input to the processor 114 via a second selector coupling 104b, and the third selector 102c provides selection input to the processor 114 via a third selector coupling 104c. In an embodiment, the selector coupling 104 is integrated with the selector 102 or forms the selector 102. For example, the selector coupling may be formed by two separate wires or conductors that overlap but do not contact each other at an actuation location, then pressure between two fingers can cause the separate wires or conductors to contact each other and complete a closed circuit. While FIG. 1 depicts three selectors 102 and three selector couplings 104, in some embodiments more than three selectors 102 and selector couplings 104 may be employed in the glove-based input device 100. In another embodiment, less than three selectors 102 and selector couplings 104 may be employed by the glove-based input device 100.

In an embodiment, the selectors 102 may be retained in finger portions of the glove 120. While depicted in FIG. 1 located proximate to finger tips of the glove 120, the selectors 102 may be located at other positions along the fingers of the glove 120. In an embodiment, three selectors 102 may be retained in each of the four finger portions of the glove 120, hence twelve selectors 102 may be retained in the finger portions of the glove 120. In another embodiment, however, a different number of selectors 102 and/or a different location of the selectors 102 may be implemented. The selector couplings 104 may be any structure suitable for communicatively conveying the actuation of the selector 102 to the processor 114. In an embodiment, the selector couplings 104 may be wire pairs. In other embodiments, the selector couplings may be some other structure. While in FIG. 1 the selector couplings 104 are shown as routing from the selectors 102 on the underside of the fingers of the glove 120 to the topside of the fingers of the glove 120 and back along the topside of the glove 120 to the processor 114, in another embodiment the selector couplings 104 may be routed from the selectors 102 to the processor 114 via a different path or paths.

The motion sensor 106 detects motion in at least one axis of motion. In an embodiment, a plurality of motion sensors 106 and/or a multi-axis motion sensor 106 may be used to sense motion in a plurality of axes of motion. The motion sensor(s) 106 detects one or more of translational motion in an x-axis, a y-axis, and a z-axis and/or rotational motion about the x-axis, the y-axis, and the z-axis. In an embodiment, the motion sensor 106 may comprise one or more accelerometers. In an embodiment, the motion sensor 106 may comprise one or more gyro sensors. The motion sensor 106 is suitable for sensing and/or detecting gestures and conveying gesture inputs to the processor 114 via the motion coupling 108. The motion sensor 106 may be retained in a palm portion or area of the glove 120, in a back-of-hand portion or area of the glove 120, or in a different area of the glove 120. The motion coupling 108 may be any structure suitable for communicatively conveying the sensed motion cues from the motional sensor 106 to the processor 114.

The processor 114 may be any of a variety of microprocessors, processors, controllers, microcontrollers, digital signal processors, application specific integrated circuits, gate arrays, programmable logic devices, and other logic circuits. The processor 114, among other functions, receives inputs from the selectors 102 and the motion sensor 106 and formats or conditions the information for transmission by the transmitter 110. For example, the processor 114 may convert analog inputs from the selectors 102 and the motion sensor 106 to digital signals. The processor 114 may modulate signals derived from the inputs from the selectors 102 and the motion sensor 106 and up-convert the modulated signals to a radio frequency for radio transmission by the transmitter 110. In another embodiment, the processor may modulate signals derived from the inputs from the selectors 102 and the motion sensor 106, and the transmitter 110 may up-convert the modulated signals to a radio frequency. In another embodiment, however, the processor 114 may transmit the selection and motion inputs over a wired link to an electronic device (not shown), for example a desktop computer, a laptop computer, a gaming system, a media player, or other electronic device.

The processor 114 may provide excitation signals to the selectors 102 and/or the motion sensor 106. The processor 114 may detect the state or activation of the selectors 102 by placing a voltage on a first wire of the selector coupling 104 and sensing the voltage on a second wire of the selector coupling, wherein an unactuated selector 102 may be associated with a voltage difference between the first and second wire of the selector coupling 104 (e.g., an open circuit across the selector 102) and an actuated selector 102 may be associated with a substantially equality of voltage between the first and second wire of the selector coupling 104 (e.g., a closed circuit across the selector 102). The processor 114 may debounce or smooth the state transitions of the selectors 102. The processor 114 may filter or otherwise condition the output of the motion sensor 106. The processor 114 may be said to condition the selections or selection inputs of the selectors 102 and/or the motion inputs of the motion sensor 106. The processor 114 may be said to provide and/or promote signal conditioning. The processor 114 may be coupled to and receive power from a power source 116, for example a battery, a solar or light power converter (e.g., a solar cell), a fuel cell, a thermal energy converter, or other power source. In another embodiment, however, the processor 114 may be coupled to and receive power from a power source external to the glove-based input device 100 via a wired link, for example from an alternating current-to-direct current converter. In an embodiment, the processor 114 may be coupled to a separate power source over a wired communication link or over a separate power chord. The power source 116 may be connected at one end to a reference 118, for example an electrical reference such as a ground or a ground plane. The processor 114 may distribute power to the other components of the glove-based input device 100, for example to the transmitter 110.

The transmitter 110 wirelessly transmits the selection and motion inputs received from the processor 114 via the wireless emitter 112 to an electronic device (not shown). The transmitter 110 modulates the selection and motion inputs for transmitting wirelessly to the electronic device. For example, the transmitter may transmit the selection and motion inputs using radio communication. In an embodiment, the transmitter 110 may transmit using Bluetooth radio communication techniques, but in other embodiments other radio communication techniques may be employed. The transmitter 110 may transmit using WiFi or industrial, scientific, and medical (ISM) radio communication techniques. In an embodiment, the wireless emitter 112 may be a radio antenna. In an embodiment, the transmitter 110 may transmit using optical communication techniques, for example using infrared optical communication techniques.

While described as separate components, one or more of the components 102-118 may be combined or integrated together. For example, the processor 114 and the transmitter 110 may be combined or integrated in a single component. The wireless emitter 112 and the transmitter 110 may be combined. These and other combinations and integrations are contemplated by the present disclosure.

In an embodiment, the transmitter 110 may be provided by a radio transceiver operable to receive as well as to transmit radio communications. In this embodiment, it is contemplated that the glove-based input device 100 may receive configuration inputs from an electronic device (not shown) to configure sensitivity levels of the selectors 102 and/or the motion sensor 106. The configuration inputs may also configure operational modes of the glove-based input device 100. When embodied as a radio transceiver, the transmitter 110 may further receive feedback signals and/or transducer signals. The processor 114 may transmit the feedback signals and/or transducer signals to the transducer 122 to provide information to a user of the glove-based input device 100. For example, the transducer 122 may provide feedback from a gaming application, feedback from a multi-media presentation system that a chart position has been advanced or reversed, and other feedback. The transducer 122 may provide feedback that a selection has been received by the electronic device (not shown) coupled to the glove-based input device 100.

The glove 120 may be constructed of any suitable material and/or fabric. In an embodiment, the glove 120 may be constructed of flexible fabric that substantially conforms to the shape of a human hand as the hand flexes and moves. In an embodiment, the glove 120 may comprise a fabric woven of threads, threads comprising natural fibers or threads comprising synthetic fibers or synthetic material. In an embodiment, the glove 120 may cover four fingers and the thumb of a hand. In another embodiment, however, the glove 120 may not cover the thumb and/or may not cover all four fingers. The selectors 102, the motion sensor 106, the transmitter 110, the selector couplers 104, the motion sensor coupler 108, the wireless emitter 112, the processor 114, the power source 116, and the reference 118 may be woven into the fabric of the glove 120 or may be enclosed between multiple layers of fabric forming the glove 120. The components 102-118 may be adhered to the inside or outside surface of the fabric forming the glove 120. In an embodiment, the components 102-118 may be manufactured into the fabric of the glove 120. In an embodiment, the selector couplers 102 and the navigator coupler 108 may be composed of flexible circuitry. In some contexts, the glove 120 may be referred to as a glove structure. In some contexts, the selectors 102, the selector couplings 104, the motion sensor 106, the motion coupling 108, the transmitter 110, the wireless emitter 112, the processor 114, the power source, the electrical reference 118, and the transducer 122 may be said to be retained by the glove 120 or by the glove structure.

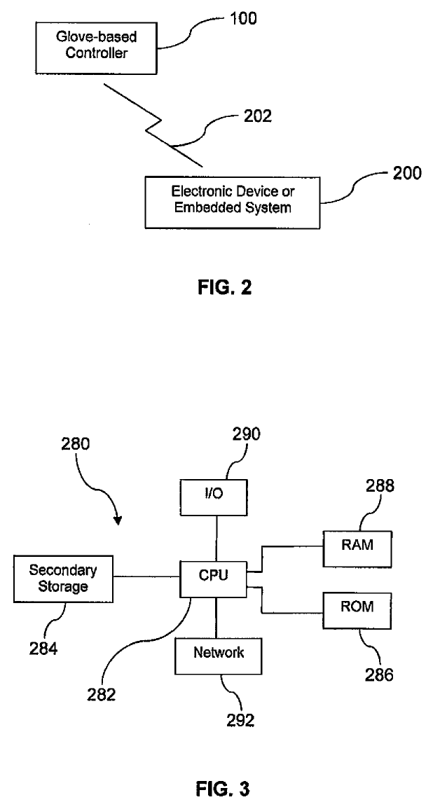

Turning now to FIG. 2, the glove-based input device 100 is shown in wireless communication with an electronic device 200 via wireless link 202. In another embodiment, however, the glove-based input device 100 may communicate with the electronic device 200 via a wired link. The electronic device 200 may be an electronic gaming platform, a multi-media presentation system, a media player, or other electronic device. In an embodiment, the electronic device 200 may be a flight control input receiver for controlling an aircraft. In an embodiment, the electronic device 200 may be a control input receiver for controlling a remotely controlled vehicle. The glove-based input device 100 may promote a user wearing the glove-based input device 100 to actuate selector inputs by, for example, pressing his thumb into a selector 102 located in or on the glove 120, at a position proximate to the tip of his index finger. The selector input may select, for example, a play mode of operation of a media player or a jump motion of a character in an electronic game. The selector input may select a slide advance mode of a multi-media presentation system.

The glove-based input device 100 may detect gesture inputs and provide the gesture inputs to the electronic device 200. Alternatively, the glove-based input device 100 may sense motion, provide the motion sense inputs to the electronic device 200, and the electronic device 200 may analyze the motion sense inputs to detect a gesture and respond to the gesture input appropriately.

Portions of the glove-based input device 100 described above may be implemented, at least in part, in a structure similar to a computer with sufficient processing power, memory resources, and network throughput capability to handle the necessary workload placed upon it. FIG. 3 illustrates a typical computer structure suitable for implementing one or more embodiments disclosed herein. The computer system 280 includes a processor 282 (which may be referred to as a central processor unit or CPU) that is in communication with memory devices including secondary storage 284, read only memory (ROM) 286, random access memory (RAM) 288, input/output (I/O) devices 290, and network connectivity devices 292. The processor may be implemented as one or more CPU chips.

It is understood that by programming and/or loading executable instructions onto the computer system 280, at least one of the CPU 282, the RAM 288, and the ROM 286 are changed, transforming the computer system 280 in part into a particular machine or apparatus having the novel functionality taught by the present disclosure. It is fundamental to the electrical engineering and software engineering arts that functionality that can be implemented by loading executable software into a computer can be converted to a hardware implementation by well known design rules. Decisions between implementing a concept in software versus hardware typically hinge on considerations of stability of the design and numbers of units to be produced rather than any issues involved in translating from the software domain to the hardware domain. Generally, a design that is still subject to frequent change may be preferred to be implemented in software, because re-spinning a hardware implementation is more expensive than re-spinning a software design. Generally, a design that is stable that will be produced in large volume may be preferred to be implemented in hardware, for example in an application specific integrated circuit (ASIC), because for large production runs the hardware implementation may be less expensive than the software implementation. Often a design may be developed and tested in a software form and later transformed, by well known design rules, to an equivalent hardware implementation in an application specific integrated circuit that hardwires the instructions of the software. In the same manner as a machine controlled by a new ASIC is a particular machine or apparatus, likewise a computer that has been programmed and/or loaded with executable instructions may be viewed as a particular machine or apparatus.

The secondary storage 284 is typically comprised of one or more disk drives or tape drives and is used for non-volatile storage of data and as an over-flow data storage device if RAM 288 is not large enough to hold all working data. Secondary storage 284 may be used to store programs which are loaded into RAM 288 when such programs are selected for execution. The ROM 286 is used to store instructions and perhaps data which are read during program execution. ROM 286 is a non-volatile memory device which typically has a small memory capacity relative to the larger memory capacity of secondary storage. The RAM 288 is used to store volatile data and perhaps to store instructions. Access to both ROM 286 and RAM 288 is typically faster than to secondary storage 284.

I/O devices 290 may include printers, video monitors, liquid crystal displays (LCDs), touch screen displays, keyboards, keypads, switches, dials, mice, track balls, voice recognizers, card readers, paper tape readers, or other well-known input devices.

The network connectivity devices 292 may take the form of modems, modem banks, ethernet cards, universal serial bus (USB) interface cards, serial interfaces, token ring cards, fiber distributed data interface (FDDI) cards, wireless local area network (WLAN) cards, radio transceiver cards such as code division multiple access (CDMA) and/or global system for mobile communications (GSM) radio transceiver cards, and other well-known network devices. These network connectivity devices 292 may enable the processor 282 to communicate with an Internet or one or more intranets. With such a network connection, it is contemplated that the processor 282 might receive information from the network, or might output information to the network in the course of performing the above-described method steps. Such information, which is often represented as a sequence of instructions to be executed using processor 282, may be received from and outputted to the network, for example, in the form of a computer data signal embodied in a carrier wave

Such information, which may include data or instructions to be executed using processor 282 for example, may be received from and outputted to the network, for example, in the form of a computer data baseband signal or signal embodied in a carrier wave. The baseband signal or signal embodied in the carrier wave generated by the network connectivity devices 292 may propagate in or on the surface of electrical conductors, in coaxial cables, in waveguides, in optical media, for example optical fiber, or in the air or free space. The information contained in the baseband signal or signal embedded in the carrier wave may be ordered according to different sequences, as may be desirable for either processing or generating the information or transmitting or receiving the information. The baseband signal or signal embedded in the carrier wave, or other types of signals currently used or hereafter developed, referred to herein as the transmission medium, may be generated according to several methods well known to one skilled in the art.

The processor 282 executes instructions, codes, computer programs, scripts which it accesses from hard disk, floppy disk, optical disk (these various disk based systems may all be considered secondary storage 284), ROM 286, RAM 288, or the network connectivity devices 292. While only one processor 292 is shown, multiple processors may be present. Thus, while instructions may be discussed as executed by a processor, the instructions may be executed simultaneously, serially, or otherwise executed by one or multiple processors.

Further embodiments and details are disclosed in Appendix A attached hereto and incorporated herein by reference for all purposes.

While several embodiments have been provided in the present disclosure, it should be understood that the disclosed systems and methods may be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted or not implemented.

Also, techniques, systems, subsystems, and methods described and illustrated in the various embodiments as discrete or separate may be combined or integrated with other systems, modules, techniques, or methods without departing from the scope of the present disclosure. Other items shown or discussed as directly coupled or communicating with each other may be indirectly coupled or communicating through some interface, device, or intermediate component, whether electrically, mechanically, or otherwise. Other examples of changes, substitutions, and alterations are ascertainable by one skilled in the art and could be made without departing from the spirit and scope disclosed herein.

What is claimed is:

1. A glove-based input device, comprising:
at least one selector;
at least one motion sensor;
a processor to receive a selection input from the at least one selector and a motion input from the at least one motion selector;
a transmitter in communication with the processor configured to wirelessly transmit the selection input and the motion input to an electronic device; and
a glove structure adopted for placing over a hand that retains the selector, the motion sensor, the processor, and the transmitter.

2. The glove-based input device of claim 1, wherein the at least one selector comprises a switch.

3. The glove-based input device of claim 2, wherein the switch is mechanically biased open and closes responsive to pressure.

4. The glove-based input device of claim 1, wherein at least one of the at least one selector is located proximate to a finger tip of the glove structure.

5. The glove-based input device of claim 1, wherein the at least one selector comprises twelve selectors, wherein three selectors of the twelve selectors are retained by each of four fingers of the glove structure.

6. The glove-based input device of claim 1, wherein the at least one motion sensor comprises at least one accelerometer.

7. The glove-based input device of claim 1, wherein the at least one motion sensor comprises at least one gyro sensor.

8. The glove-based input device of claim 1, wherein the at least one motion sensor comprises a multi-axis motion sensor.

9. The glove-based input device of claim 1, wherein the processor conditions the selection inputs from at least one of the selection inputs and the motion inputs before the transmitter wirelessly transmits the selection inputs and motion inputs.

10. The glove-based input device of claim 1, further comprising a transducer, wherein the processor transmits outputs to the transducer and wherein the glove structure retains the transducer.

11. The glove-based input device of claim 4, wherein the transducer is one of a vibrator, a heater, a light emitting diode (LED), a liquid crystal display (LCD), a visual display, and a speaker.

12. The glove-based input device of claim 1, wherein the transmitter wirelessly transmits based on at least one of WiFi wireless communication technology, BlueTooth wireless communication technology, and industrial-scientific-medical (ISM) wireless communication technology.

13. The glove-based input device of claim 1, further including a power source, wherein the processor receives power from the power source and the glove structure retains the power source.

14. A glove-based input device, comprising:
at least one selector;
at least one motion sensor;
a processor to receive a selection input from the selector and a motion input from the motion selector and to communicate the selection input and the motion input via a wired communication link to an electronic device; and
a glove structure adopted for placing over a hand that retains the selector, the motion sensor, and the processor.

15. The glove-based input device of claim 14, wherein the processor receives power through one of the wired communication link or a power chord.

16. A glove-based input device, comprising:
a glove structure adopted for placing over a hand;
a plurality of switches retained by finger portions of the glove structure, wherein the switches are mechanically biased open and are operable to be closed when pressure is applied between a thumb and the switch and wherein each switch is operable to provide an indication of an open state and a closed state;
an at least one motion sensor retained by one of a palm portion of the glove structure and a back-of-hand portion of the glove structure, wherein each motion sensor is operable to provide an indication of motion; and
a processor in communication with the switches and the motion sensor and operable to transmit indications of the state of the switches and motion indications to an electronic device to provide inputs to the electronic device.

17. The glove-based input device of claim 16, wherein the glove structure comprises a fabric woven or nonwoven of threads.

18. The glove-based input device of claim 16, further comprising a feedback component comprising at least one of a vibrator, a light emitting diode (LED), a liquid crystal display (LCD), a visual display, a heater, and a speaker.

19. The glove-based input device of claim 16, further including a wireless transmitter in communication with the processor, wherein the processor transmits to the electronic device by a wireless communication link promoted by the transmitter.

20. The glove-based input device of claim 16, wherein the processor transmits to the electronic device by a wired communication link.
